(19) United States
(12) Patent Application Publication
(10) Pub. No.: US 2012/0275105 A1
(43) Pub. Date: Nov. 1, 2012

(54) Metal-Coated Hard Disk Drives and Related Methods

(75) Inventor: James E. McGuire, JR., Westerville, OH (US)

(73) Assignee: ENTROTECH, INC., Columbus, OH (US)

(21) Appl. No.: 13/096,480

(22) Filed: Apr. 28, 2011

(51) Int. Cl. H05K 5/04; G11B 5/105

(52) U.S. Cl. 361/679.33; 29/603.03

(57) ABSTRACT

A hard disk drive of the invention comprises at least one metal coating formed over at least one exterior surface of a hard disk drive housing, wherein the hard disk drive is hermetically sealed. Methods for forming such hard disk drives are also disclosed.

### BACKGROUND OF THE INVENTION

The present invention relates generally to metal-coated hard disk drives and related methods.

A disk drive is a device used to store information in a computing environment. In a disk drive, data is generally recorded on planar, round, rotating surfaces (which are commonly referred to as disks, discs, or platters). There are several types of disk drives, including optical disk drives, floppy disk drives, and hard disk drives. Nowadays, hard disk drives tend to be most common. Strictly speaking, “drive” refers to a device distinct from its medium, such as a tape drive and its tape, or a floppy disk drive and its floppy disk. A hard disk drive (sometimes referred to as a HDD), also referred to as a hard drive, hard disk, or fixed disk drive, is a non-volatile storage device that stores digitally encoded data on rapidly rotating platters with magnetic surfaces. Early hard disk drives had removable media; however, a HDD today is typically an encased unit with fixed media.

A typical hard disk drive includes a head disk assembly (HDA) and a printed circuit board assembly (PCBA) attached to a disk drive base of the HDA. The HDA typically includes at least one magnetic disk, a spindle motor for rotating the disk, and a head stack assembly (HSA) having an actuator assembly with at least one transducer head, typically several, for reading and writing data from the disk. The PCBA includes a servo control system in the form of a disk controller for generating servo control signals. The HSA is controllably positioned in response to the generated servo control signals from the disk controller. In so doing, the attached heads are moved relative to tracks disposed upon the disk. The heads are typically distanced from the magnetic disk by a gaseous cushion—so that they are said to “fly” over the disk. Thus, it is important that the position of the heads be well-controlled for proper reading and writing from the disk.

Hard disk drives are generally sealed to prevent dust and other external sources of contamination from interfering with operation of the hard disk heads therein. Some hard disk drives are hermetically sealed. A hermetic seal is generally understood to be an airtight seal. Note that some seals (e.g., those “sealing” air within the hard disk drive) are not literally air tight, but rather utilize an extremely fine air filter in conjunction with air circulation inside the hard drive enclosure. The spinning of the disks causes air to circulate therein, forcing any particulates to become trapped on the filter. The same air currents also act as a gas bearing, which enables the heads to float on a cushion of air above the surfaces of the disks. However, “hermetically” sealed means that the seal is so airtight that the disk drive's internal pressure is substantially independent of the external or ambient pressure. This is in contrast to a conventional or non-hermetically sealed disk drive that has a breather port with a filter in a wall of the base plate or cover for equalizing the disk drive's internal pressure with the external pressure. Thus, a hermetically sealed drive does not contain a breather port.

Within a hermetically sealed hard disk drive, gases other than atmospheric air are often employed. Filling the sealed environment of a hard disk drive with gases other than air can enhance their performance. For example, use of lower density inert gases, such as helium, can reduce aerodynamic drag between the disks and their associated read/write heads by a factor of approximately five-to-one as compared to their operation in air. This reduced drag beneficially results in reduced power requirements for the spindle motor. A helium-filled drive, thus, uses substantially less power than a comparable hard disk drive operating in an air environment. At the same time, the helium gas also conducts heat generated during operation of the disk drive away more effectively than air.

Hermetically sealed hard disk drives are first filled with a desired gaseous medium (whether it be atmospheric air or one or more other gases) before operation. Then, if the constituency of the gaseous medium substantially changes due to leakage of the hard disk drive housing, the hard disk drive must be either discarded or refilled with the desired gaseous medium. Filling disk drives to a desired pressure and concentration of gaseous components, however, can be both time-consuming and difficult. A number of patent documents focus on providing and/or replenishing gases such as helium at a desired concentration within a hard disk drive. See, for example, U.S. Patent Publication Nos. 2003/0081349 and 2003/0089417. Also see U.S. Pat. No. 6,560,064.

Due to imperfect sealing of hard disk drive housings, the benefits of using lower density gases such as helium are conventionally not longstanding. Potential paths of leakage (allowing both air flow into the hard disk drive housing and allowing gas outflow from the hard disk drive housing) include those paths existing at the junction of two mating components thereof. Those components include, for example, screws or other mechanical fasteners used to conventionally fasten multiple parts of the housing together. In addition, gasket seals and the like used to improve the seal between multiple components are often susceptible to at least some leakage. As gas such as helium leaks out of a sealed hard disk drive, air leaks in (or vice versa), causing undesirable effects in the operation of the disk drives—even possibly causing the disk drives to catastrophically fail. For example, an increased concentration of air inside the hard disk drive may increase forces on the read/write head therein due to turbulent airflow within the drive. Further, such undesired air may cause the read/write heads to “fly” at too great a distance above the disks. The risk of unexpected failure due to inadequate concentration of helium within such drives is a considerable drawback to helium-filled disk drives, particularly since the data stored within the disk drive can be irretrievably lost if the disk drive fails.

Therefore, as discussed in U.S. Patent Publication No. 2003/0179489, despite the advantages of helium-filled drives, such drives have not been commercially successful. This is mainly due to problems associated with leakage of gas from within the drives over time. Unlike air-filled disk drives, helium-filled drives do not include a filtered port to equalize the pressure within the drive to the ambient pressure—which ensuing pressure differential contributes to increased leakage of gas. Thus, while prior art helium drives are completely “sealed” in the conventional sense, it is still possible for helium gas therein to leak out past conventional rubber gasket seals used to seal the top cover to the drive base. Such leakage is not surprising given the relatively smaller size (i.e., lower atomic weight) of the helium atoms in comparison to the constituent gases found in air (i.e., nitrogen and oxygen). That is, the rubber gasket seals on prior art drives allow the relatively smaller helium atoms to diffuse through the rubber membrane. Indeed, such prior art gasket seals do not provide hermetic seals with respect to air (i.e., the gasket seals are also permeable to the larger atoms of nitrogen and oxygen in air) since it is air that typically displaces the helium gas that leaks from the drive.

Most prior art gasket seals are only intended to keep relatively large contaminants such as dust or smoke from the interior of a disk drive. However, such gasket seals are preferred as compared to other, more permanent methods of sealing a drive for two main reasons. First, such seals typically do not outgas and, thus, do not contribute to the contamination of the interior of the drive. Secondly, such seals may be reused if necessary during the assembly of the disk drive, such as when an assembled drive fails to pass certification testing and must be “re-worked.” Re-working a drive typically entails removing the top cover from the base and replacing a defective disk or read/write head while the drive is still in a clean room environment. The re-worked drive is then reassembled, which can even be done using the same rubber gasket seal positioned between the base and the top cover. Unfortunately, however, while such gasket seals are convenient, they simply often do not provide a sufficient hermetic seal to maintain the required concentration of helium (or other low density gas) within the disk drive for the desired service life of the drive.

In view of the potential for long-term performance problems, U.S. Patent Publication No. 2003/0179489 describes a disk drive assembly having a sealed housing. As described therein, a disc drive includes a base plate supporting a spindle motor and an actuator assembly. A structural cover is removably attached to the base plate to form an internal environment within the disc drive. The internal environment of the drive is filled with a low density gas such as helium, and a sealing cover is permanently attached to the base plate and the structural cover to form a hermetic seal that maintains a predetermined concentration of the low density gas within the internal environment over a service lifetime of the disc drive.

The disc drive further includes a first seal secured between the base plate and the structural cover to prevent contaminants from entering the internal environment of the disc drive. The first seal is formed from a material such as rubber that allows leakage of the low density gas from the internal environment at a sufficiently low rate so that the disc drive may be operated for a predetermined period of time in the absence of the sealing cover.

In one embodiment, the base plate includes a raised outer edge and the sealing cover includes a downward depending edge that is adhesively bonded within a groove formed between an outer surface of the structural cover and the raised outer edge of the base plate. Alternatively, the sealing cover may include a downward depending edge that is adhesively secured to an outer perimeter wall of the base plate. In an alternative embodiment, the sealing cover is soldered to a top surface of the raised outer edge of the base plate. Such assemblies purportedly create a hermetic seal that will maintain desired concentrations of helium (or other low density gases) within the drive over the operational lifespan of the drive (e.g., leaking helium at such a low rate that it would take over seventy years for the helium concentration to drop below a predetermined lower limit). However, such sealing covers are not without their limitations—e.g., those dimensional limitations discussed in U.S. Patent Publication No. 2003/0179489 and the potential interference of such sealing covers with electrical connectors, such as those associated with flex circuitry protruding from the disk drive. Thus, improvements are still needed.

In addition, while U.S. Patent Publication No. 2003/0223148 (corresponding to U.S. Pat. No. 7,119,984) discusses improved containment of helium within a hard disk drive, the methods therein rely on laser-based metal sealing of such drives. Further, such “sealing” of drives is incomplete in that it does not prevent leakage through valves and ports used to inject gas into disk drive housings once sealed as such. As described therein, a base can be combined with a cover by overlapping respectively corresponding coupling flanges of the base and cover with each other. The coupling flanges are then described as being jointed and fastened together by spot welding, but only if both of the base and cover are made of metal including iron. Alternatively, hermetic sealing to some extent is said to be guaranteed if seam-welding is effected by continuously carrying out spot welding. Alternatively, when the base and the cover are made of a metal other than iron or a resin material, the coupling flanges are described as being joined together by means such as wrap-seaming, screws, or riveting. Still further, if both the base and cover are made of metal including aluminum or made of a resin material, the coupling flanges are stated to be preferably jointed and fastened together by screws or rivets. Further, in the outer peripheral portion of the jointed coupling flanges, a frame composed of a pair of L-shaped frame elements can be attached to force the jointed coupling flanges to be closed up tightly. Each of these L-shaped frame elements are made of so-called engineering plastic, e.g., polyamide resin or polyphenylene sulfide resin, and have a sectional form with a recess corresponding to the outer shape of the jointed coupling flanges. In this case, the L-shaped frame elements are fixed to the jointed coupling flanges of the housing by adhesive or by welding the frame elements per se. Also see U.S. Pat. No. 6,762,909 for a description of laser welding of a disk drive's cover and base plate made of aluminum or other alloys. Similarly, U.S. Pat. No. 5,608,592 discusses how spot welding can be used to secure a base and cover of a disk drive housing.

U.S. Pat. No. 4,686,592 discloses a housing comprising a lower body portion and a cover portion. Lower body portion is stated to be cylindrical in shape, having a lip located towards the outer periphery and a ledge associated therewith. Cover portion is stated to have a lip portion along its outer periphery. The inner and outer diameter of the lips are selected so that the two lips nest with one another when the cover portion is placed over the lower body portion, i.e., the outer diameter of the lower body portion's lip is selected to be greater than the inner diameter of the cover portion's lip. Further, the height of the cover portion's lip is selected with respect to the height of the lower body portion's lip so that a groove is formed for accommodating the outer periphery of the disk. Adhesives, such as epoxy, can be applied in the groove to assist in fixedly securing the disk within the groove. The disk is further secured in the groove by the clamping action provided by the cover portion and the lower body portion. Alternative methods for securing the cover portion to the lower body portion described therein include: threading, cam-locking, radial crimping, laser welding, ultrasonic welding, and the like.

U.S. Pat. Nos. 6,392,838 and 6,525,899 disclose a disk drive assembly purportedly hermetically encased within a metallic can. The metallic can comprises a top and bottom housing. Each housing component includes a sealing flange extending around its periphery. After the disk drive assembly is securely placed into the bottom housing, the top and bottom housings are mated and sealed together by forming a seam seal with the seal flanges. Also disclosed is use of a metallic gasket seal having a C-shaped cross-sectional area to purportedly hermetically seal a disk drive assembly. The C-seal includes a base layer and a plating layer, with the length of the seal extending the periphery of the disk drive base, similar to conventional elastomer gasket seals. After the disk drive cover is placed over the disk drive base and C-seal, the cover is clamped, thus compressing the C-seal. The resulting compression forces the plating layer to fill surface asperities in the area of the disk drive cover and base that contact the C-seal. These configurations purportedly provide assemblies with atmosphere leak rates of less than one cubic centimeter per 10⁸ seconds or 5% of the volume of the sealed atmosphere over ten years.

U.S. Pat. No. 5,454,157 describes a disk drive assembly containing a metallic base and cover. In order to minimize escape of helium or nitrogen contained therein (via porosity in the metallic base and cover plates), a special electrostatic coating process and material called “E-coat” are used. E-coating, which is said to be a commercially available coating material and is known to be an insulative epoxy material, is applied to the surfaces of the base and cover as well as all other surfaces making up the hermetically sealed chamber. Such application of the E-coating takes place before the plates are assembled together. Every surface, inner and outer, of each plate is completely coated with a black E-coating as such. With the E-coating applied, the overall sealed chamber's porosity is purportedly lowered ninety-seven percent to an acceptable amount in order to contain the helium and nitrogen gas.

Elimination of or minimization of leakage is desired for not only better containment of gas within a hard disk drive, but for other reasons as well. One such reason relates to a reduction of complications arising from electromagnetic interference. Electromagnetic interference (“EMI,” also called radio frequency interference or “RFI”) is a usually undesirable disturbance caused in an electrical circuit by electromagnetic radiation emitted from an external source. Such disturbance may interrupt, obstruct, or otherwise degrade or limit the effective performance of the circuit. EMI can be induced intentionally for radio jamming, as in some forms of electronic warfare, or unintentionally, as a result of spurious emissions and responses, intermodulation products, and the like. A source of EMI may be any object, artificial or natural, that carries rapidly changing electrical currents, such as another electrical circuit or even the sun or Northern Lights. Broadcast transmitters, two-way radio transmitters, paging transmitters, and cable television are also potential sources of EMI within residential and commercial environments. Other potential sources of EMI include a wide variety of common household devices, such as doorbell transformers, toaster ovens, electric blankets, ultrasonic pest controls (e.g., bug zappers), heating pads, and touch-controlled lamps. It is known that EMI frequently affects the reception of AM radio in urban areas. It can also affect cell phone, FM radio, and television reception, although to a lesser extent. EMI can similarly affect performance of a computer.

In conventional disk drives, unwanted and potentially problematic EMI wavelengths can enter a disk drive through a number of places. For example, similar to paths of gas leakage, such wavelengths can enter disk drive housings around screws used to hold multiple components of the housing together.

Within integrated circuits, the most important means of reducing EMI are: the use of bypass or “decoupling” capacitors on each active device (connected across the power supply and as close to the device as possible), risetime control of high-speed signals using series resistors, and V_{CC} filtering. If all of these measures still leave too much EMI, shielding such as using radio frequency (RF) gasket seals (which are often very expensive) and copper tape has been employed. Another method of reducing EMI is via use of metal hard disk drive components. While the use of metal components undesirably increases the overall weight of an apparatus, use of metal components has been conventionally mandated in the hard disk drive industry due to the EMI sensitivity of mechanical spinning components therein. Without mechanical spinning components therein, however, manufacturers of flash drives have taken advantage of the benefits of, for example, a plastic case for enclosure of the drive. See, for example, U.S. Pat. No. 7,301,776, which describes how metal material used for top and bottom plates of the drives described therein can be replaced by plastic as there are fewer EMI issues associated with flash memory devices as compared to mechanical spinning hard disk drives.

Another source of potential hard disk drive failure stems from electrostatic discharge (ESD). ESD refers to a sudden and momentary electric current that flows between two objects at different electrical potentials. The term is usually used in the electronics and other industries to describe momentary unwanted currents that may cause damage to electronic equipment. Ways to eliminate problematic ESD are in need of improvement as performance demands of hard disk drives increase.

While the aforementioned problems typically arise based on events and/or materials external to a disk drive, other problems may arise based on events and/or materials internal to a disk drive. That is, design of components within conventional disk drives can contribute to hard disk drive failure. For example, plastic components are susceptible to outgassing and components made from conductive materials are prone to shedding of particles, both of which can cause catastrophic disk failure.

In view of the number of potential problems impacting effective and long-term performance of hard disk drives, alternative methods and apparatus for improved hard disk drives are desired. Most desired are those methods and apparatus with improved efficiency and reliability over conventional attempts to provide the same.

### SUMMARY OF THE INVENTION

Hard disk drives according to the invention comprise at least one metal coating formed over at least one exterior surface of a hard disk drive housing, wherein the hard disk drive is hermetically sealed. In a further embodiment, the at least one metal coating is formed over essentially the entire exterior surface of the hard disk drive housing. Advantageously, exemplary hard disk drives of the invention are capable of providing and maintaining an adequate sealed environment for a gaseous medium other than atmospheric air for at least five years.

According to one embodiment, the at least one metal coating is formed over a portion of an electrical connector proximate exit of the electrical connector from the hard disk drive housing. According to another embodiment, the at least one metal coating is formed over a fill port used to fill the hard disk drive with a gaseous medium. Although the hard disk drive is metal-coated, at least a major portion of the hard disk drive housing comprises a material that is lighter in weight than metal according to an exemplary embodiment. Many advantages are associated with the same and described further herein.

One embodiment of the hard disk drive comprises at least two metal coatings. For example, the at least one metal coating comprises multiple contiguous layers according to one aspect of this embodiment. In an exemplary embodiment, the at least one metal coating comprises at least about four individual layers.

Thickness of the at least one metal coating may vary. However, in one embodiment, the at least one metal coating comprises a uniformly thick coating of the same metal or combinations thereof on the entire exterior surface of the hard disk drive housing. According to a further embodiment, combined thickness of the one or more metal coatings is about one micron thick. According to yet a further embodiment, combined thickness of the at least one metal coating is at least about fifty microns thick. According to a still further embodiment, combined thickness of the at least one metal coating is less than about two-hundred microns thick.

In an exemplary embodiment, the at least one metal coating comprises aluminum, chrome, copper, stainless steel, or a combination thereof. According to one aspect of this embodiment, more than one metal coating is formed over the exterior surface of the hard disk drive housing, with the most exterior metal coating comprising chrome or stainless steel. According to another aspect of this embodiment, more than one metal coating is formed over the exterior surface of the hard disk drive housing, wherein at least one metal coating comprises a stainless steel coating having a thickness of about one micron formed over a copper coating having a thickness of at least about two microns.

A method of forming hard disk drives of the invention comprises steps of: providing a cover and a base for the hard disk drive housing; optionally, positioning a sealing material between the cover and the base for sealing engagement of the hard disk drive housing; enclosing the cover and the base around components internal to the hard disk drive; optionally, evacuating and filling the hard disk drive with a desired gaseous medium when the desired gaseous medium is other than atmospheric air; and forming the at least one metal coating on the at least one exterior surface of the hard disk drive housing. According to various aspects of such methods, the step of forming the at least one metal coating on the at least one exterior surface of the hard disk drive housing comprises using plating techniques, sputter coating, or spray coating.

### BRIEF DESCRIPTION OF THE DRAWINGS

Note that the components and features illustrated in all figures throughout this application are not necessarily drawn to scale and are understood to be variable in relative size and placement. Similarly, orientation of many of the components and features within the figures can vary such that, for example, a horizontal configuration could be readily reoriented to a vertical configuration, and vice versa, as desired.

FIG. 1 is a partial perspective view of a prior art hard disk drive with the top cover of the drive housing removed to illustrate certain features.

FIG. 2A is a top perspective view of a hard disk drive comprising at least one metal coating according to the invention.

FIG. 2B is a partial phantom top perspective view of the hard disk drive of FIG. 2A, illustrating an exemplary electrical connector thereof.

FIG. 2C is a partial cross-sectional view of the hard disk drive of FIG. 2B, taken proximate exit of the electrical connector from the hard disk drive along plane C-C of FIG. 2B.

FIG. 2D is a partial bottom perspective view of the hard disk drive of FIG. 2B, taken proximate the fill port illustrated in FIG. 2I.

FIG. 2E is a partial cross-sectional view of the hard disk drive of FIG. 2B, taken along plane E-E of FIG. 2B proximate the fill port illustrated in FIG. 2D.

FIG. 2F is a partial side perspective view of the hard disk drive of FIG. 2B, wherein the fill port of the hard disk drive is unplugged.

FIG. 2G is a partial cross-sectional view of the hard disk drive of FIG. 2B, taken along plane G-G of FIG. 2B.

FIG. 2H is a partial phantom top perspective view of a further embodiment of the hard disk drive of FIG. 2B.

FIG. 2I is a bottom perspective view of the hard disk drive of FIG. 2H.

FIG. 3 is a top perspective view of a further embodiment of a hard disk drive according to the invention.

FIG. 4 is a schematic diagram of an exemplary method of assembling and testing a hard disk drive according to the invention.

### DETAILED DESCRIPTION OF THE PREFERRED EMBODIMENTS OF THE INVENTION

The present invention is beneficially applied in conjunction with any suitable conventional hard disk drive in need of performance improvements. According to the present invention, at least one metal coating is formed over at least a portion of an exterior surface of a hard disk drive.

A disk drive assembly conventionally includes a base to which various components of the disk drive are mounted. A top cover cooperates with the base to form a housing that defines an encased environment for the disk drive. Any disk drive comprises any of a number of suitable components encased within the housing. The components within the disk drive include, for example, a spindle motor, which rotates one or more magnetic disks at a constant high speed, and an actuator assembly for writing information to and reading information from circular tracks on the disks. The actuator assembly typically includes a plurality of actuator arms extending towards the disks, with one or more flexures extending from each of the actuator arms. Mounted at the distal end of each of the flexures is a read/write head, which includes an air bearing slider enabling the head to fly in close proximity above the corresponding surface of the associated disk during operation of the disk drive. When the disk drive is powered down, the heads may be moved to a landing zone at an innermost region of the disks where the air bearing sliders are allowed to land on the disk surface as the disks stop rotating. Alternatively, the actuator assembly may move (unload) the heads beyond the outer circumference of the disks so that the heads are supported away from the disk surface by a load/unload ramp when the drive is powered down.

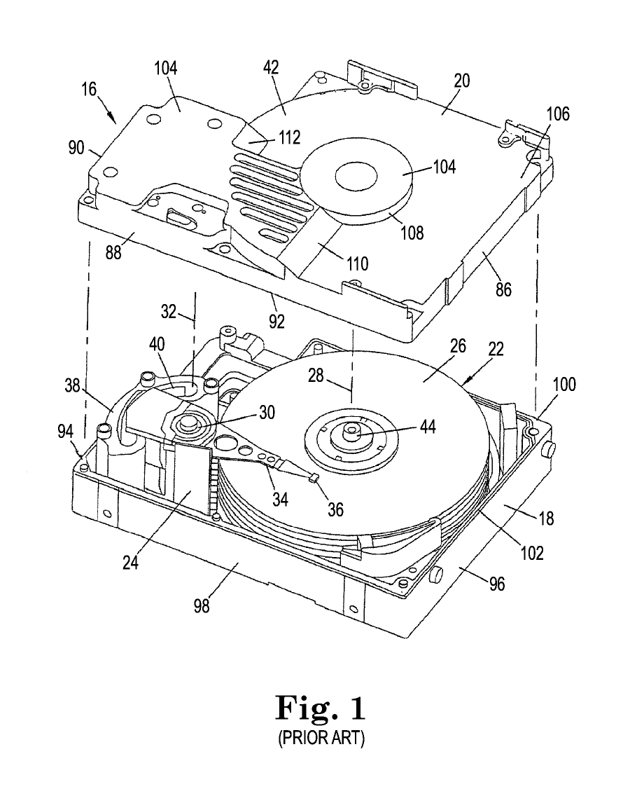

Turning now to the drawings, there is shown in FIG. 1 part of a prior art hard disk drive 16 described in U.S. Patent Publication No. 2003/0223148. The prior art hard disk drive 16 illustrated in FIG. 1 is only one example of many well-known embodiments of hard disk drives and is illustrated to show exemplary components of hard disk drives for use as a reference in conjunction with a description of the present invention. Recognize, however, that many conventional hard disk drives can be modified according to the improvements of the invention.

As shown in FIG. 1, a conventional hard disk drive 16 has a rigid outer housing including a base 18 and a cover 20. In FIG. 1, the cover 20 is removed from the base 18 to reveal a disk pack or spindle assembly 22 and a rotary actuator 24, both of which are mounted moveably with respect to the housing formed by the base 18 and cover 20. More particularly, the spindle assembly 22 includes a top disk 26 and several additional concentrically stacked and spaced-apart disks rotatable about a vertical spindle axis 28.

Rotary actuator 24 includes an actuator shaft 30 mounted to pivot relative to the base 18 about a vertical actuator axis 32. Several transducer support arms, including a top support arm 34, are fixed to rotate with the actuator shaft 30. Each arm carries a magnetic data transducing head—e.g., a transducing head 36 on a support arm 34. The rotary actuator 24 pivots to move the transducing head 36 along arcuate paths generally radially with respect to the disks. Selective actuator 24 pivoting, in combination with controlled rotation of the disks, allows reading and recording of data at any desired location at any one of the disk recording surfaces. Rotary actuator 24 is pivoted by selective application of an electrical current to a voice coil 38 supported for arcuate movement within a magnetic field created by a permanent magnet arrangement 40, which includes several magnets and a poll piece (both of which are not illustrated in further detail).

The rotary actuator 24 and spindle assembly 22 are supported between two opposed housing walls, including a top wall 42 of the cover 20 and a bottom wall of the base 18. Spindle shaft 44 and the actuator shaft 30 may be stationary—meaning that they are integral with the housing—with the disks and support arms being mounted to rotate relative to their respective shafts.

The cover 20 includes a vertical continuous sidewall structure including a rearward wall 86, a sidewall 88, and a forward wall 90. Here, the upper sidewall structure includes a generally flat, horizontal continuous bottom edge 92, though some embodiments may include a flange or other mated fitting so as to fit into a top edge 100 of base 18 facilitating a tight fit and/or laser-welding. The base 18 includes an upright wall structure including a forward wall 94, a rearward wall 96, and two opposed sidewalls, one of which is shown at 98. These walls combine to form a continuous, horizontal top edge 100. FIG. 1 also illustrates an elastomeric gasket seal 102 mounted to top edge 100 of the base 18. When the cover 20 is assembled onto the base 18, the confronting bottom edge 92 of the cover 20 and the top edge 100 of the base 18 are brought into sealing engagement to close the housing about the spindle assembly 22 and the rotary actuator 24.

The upper and lower sidewalls 88, 98 are generally relatively thick to lend rigidity to the housing. The top wall 42 of the cover 20 may be formed with a horizontal full height region 104 and a horizontal recessed region 106, the two types of regions being interconnected by several non-horizontal regions as indicated at 108, 110 and 112. One portion of the full height region 104 accommodates the rotary actuator 24 and the spindle assembly 22. The non-horizontal regions 108, 110, 112 provide additional stiffness to the top wall 42 of the cover 20, which strengthens the top wall 42 and enables a somewhat reduced thickness wall construction.

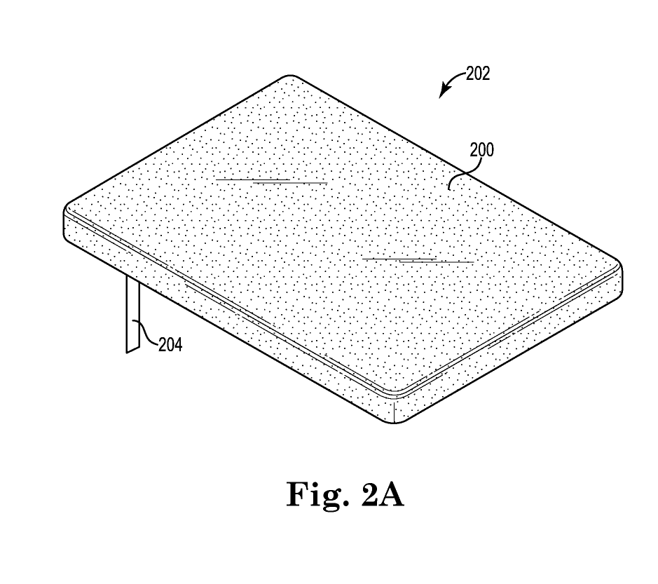

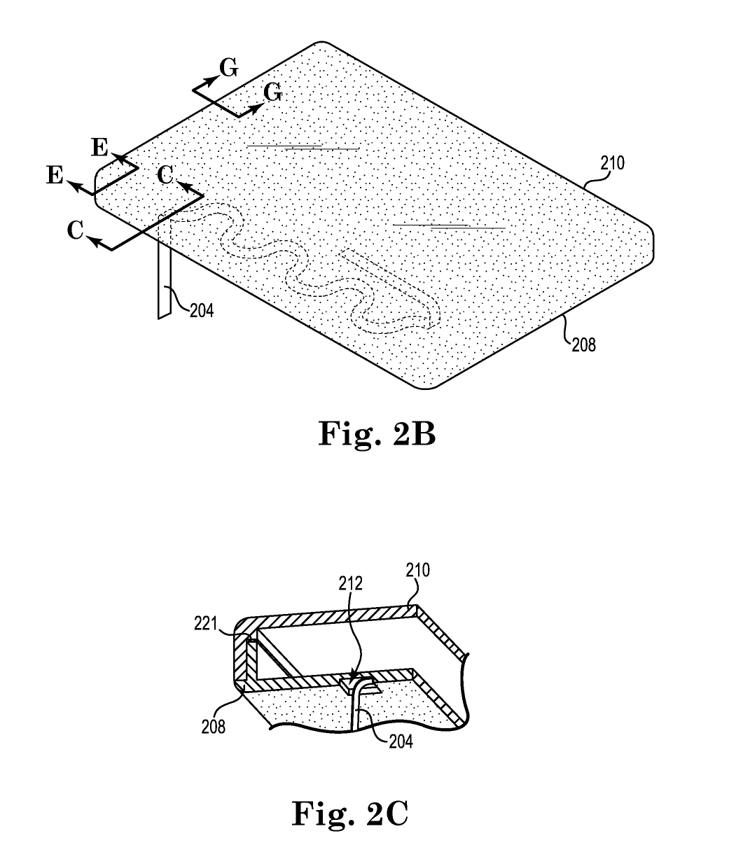

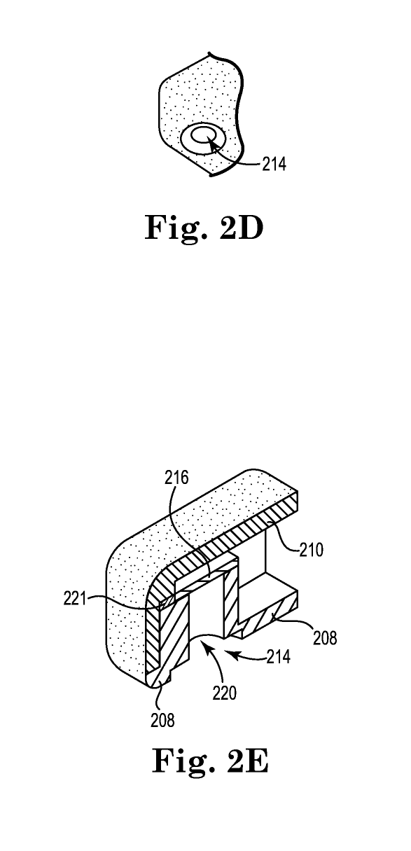

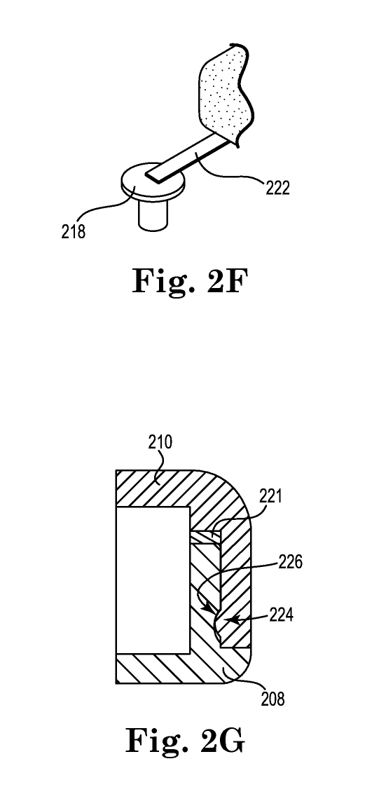

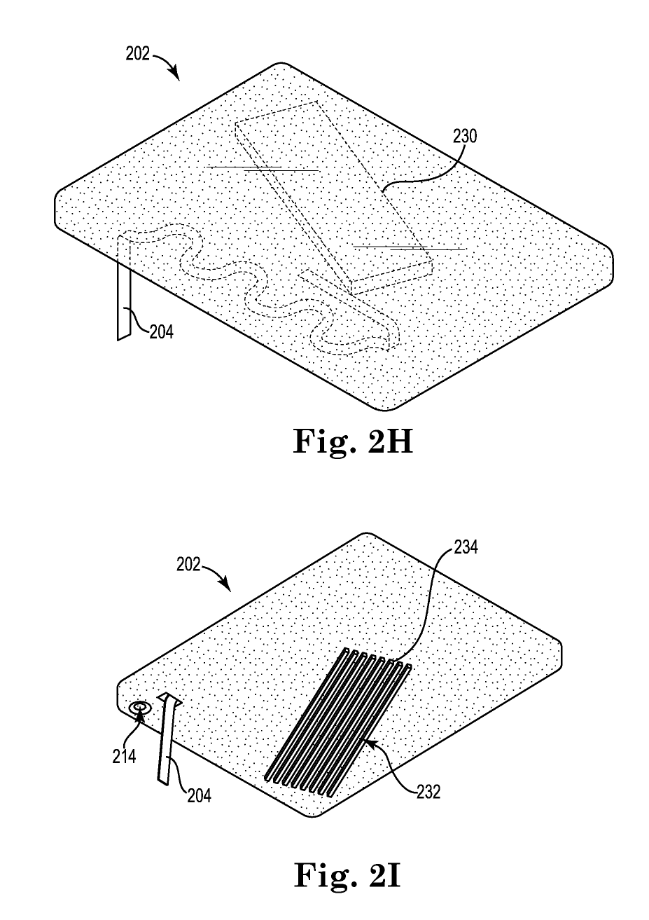

According to one embodiment of the present invention, at least one metal coating is formed over at least a portion of an exterior surface of a hard disk drive, such as for example the housing of the prior art hard disk drive 16 illustrated in FIG. 1. According to one variation of this embodiment, at least one metal coating is formed over a cover of a hard disk drive. While at least one metal coating may also be formed elsewhere on the hard disk drive, benefits of the invention may be realized in certain embodiments where essentially only the cover is coated with at least one metal coating according to the invention. For example, such may be the case when the disk drive comprises a single platter disk that is exposed to EMI through essentially only the disk drive cover. Advantageously, the at least one metal coating beneficially increases resistance to EMI according to this embodiment. However, to provide further advantages, including improved sealing of inert gases within a hard disk drive, at least one metal coating 200 is formed over essentially the entire exterior surface of the hard disk drive 202 (i.e., encapsulating an exterior surface of the hard disk drive housing) according to a further embodiment illustrated in FIG. 2A.

The at least one metal coating comprises any suitable metal according to the present invention. Understand that, as used herein, the term metal includes metal-containing compounds, such as metal oxides. The metal coating is discrete from the underlying article on which it is applied and is formed in-situ. The at least one metal coating is formed using any suitable methodology, including, for example, spray coating (e.g., plasma coating), sputter coating, or plating techniques, as known to those of ordinary skill in the art. For example, the number and duration of passes using sputter coating equipment can vary depending on the nature of the metal, component, and desired properties. Multiple passes to form multiple contiguous layers was found to reduce or eliminate potential problems associate with pinholes or other defects often found in metal coatings. As such, formation of metal coatings using multiple passes is preferred. For example, when coating a hard disk drive housing, two sputter coating passes of about ten seconds each can be used to form an adequate metal coating according to one embodiment of the invention. Any material capable of being deposited or plated may be coated on the hard disk drive using technologies as known to those of ordinary skill in the art. For example, any sputter coating target material may be used to form the at least one metal coating. In an exemplary embodiment, each metal coating according to the invention comprises aluminum, chrome, copper, stainless steel, nickel, or a combination thereof. Understand that the same metal coating need not be applied to the entire exterior surface area of the hard disk drive coated with metal according to the invention.

As used herein, a metal coating is defined as a single layer or multiple contiguous layers of essentially the same metal. The metal coating may be a continuous layer or a discontinuous layer or multiples thereof. Further, the thickness of a metal coating can vary according to the nature of the surface coated and properties desired. For example, when the hard disk drive comprises a single platter disk that is exposed to EMI through essentially only the disk drive cover as described above, a thicker metal coating may be formed over the disk drive cover as compared to the remainder of the hard disk drive. For ease of manufacture, however, it is often preferred to have a uniformly thick coating of the same metal or combinations thereof on the entire exterior surface of the hard disk drive housing.

Preferably, at least one metal coating comprises multiple layers in order to minimize the possibility of pin holes or other defects negatively impacting shielding or containment properties of the hard disk drive. In those embodiments where containment of inert gas within the hard disk drive is of concern, the at least one metal coating comprises more and/or thicker layers. When multiple layers are used, for example, the chance of defects resulting in through paths for undesired EMI and gaseous particles is minimized. The through transmission rate for such particles is essentially zero according to preferred embodiments. In one embodiment, the metal coating comprises at least two individual layers. In another embodiment, the metal coating comprises at least about four individual layers. In still another embodiment, the metal coating comprises at least about six individual layers. In yet another embodiment, the metal coating comprises at least about ten individual layers. Understand that each individual layer need not be the same thickness or type of metal; although, uniformity thereof is often preferred for process simplicity.

Generally, thickness of the one or more metal coatings depends on the nature of the surface coated and properties desired. Where containment of inert gas within the hard disk drive is of concern, the at least one metal coating has a greater thickness. When alleviation of ESD is the primary concern, the at least one metal coating need not have as great of a thickness. For example, thickness and continuity of the at least one metal coating need only be great enough as that necessary to provide sufficient conductivity to function as a Faraday-type cage when ESD is a primary concern.

According to one aspect of a preferred embodiment of the invention, combined thickness of the one or more metal coatings is about one micron thick. In another embodiment, the combined thickness of the one or more metal coatings is at least about twelve microns thick. In still another embodiment, the combined thickness of the one or more metal coatings is at least about twenty-five microns thick. In yet another embodiment, the combined thickness of the one or more metal coatings is at least about fifty microns thick. In still another embodiment, the combined thickness of the one or more metal coatings is at least about one-hundred microns thick. In yet another embodiment, the combined thickness of the one or more metal coatings is at least about four-hundred microns thick. While the one or more metal coatings may have a greater combined thickness, the combined thickness is less than about two-hundred microns according to an exemplary embodiment. Advantageously, thicker coatings are not needed in order to provide sealing functionality according to the invention. As such, an associated weight savings results and facilitates flexibility in the overall disk drive design.

As noted above, more than one metal coating may be formed on an least a portion of an exterior surface of a hard disk drive housing according to further embodiments of the invention. According to an exemplary aspect of this further embodiment, the most exterior metal coating comprises chrome or stainless steel, exemplary metals that are durable. In one such exemplary embodiment, a copper coating having a thickness of at least about two microns is formed under a stainless steel coating having a thickness of about one micron. Copper, while it may not be as durable or otherwise as desirable as chrome or stainless steel, is preferentially coated underneath another metal coating as it is typically capable of being coated at higher speeds than other metals.

According to a further embodiment of the hard disk drive illustrated in FIG. 2B, at least one metal coating 200 is also formed over a portion of an electrical connector 204 exiting the hard disk drive 202 for connection of the hard disk drive 202 to external electrical components. For example, an actuator flex cable, such as the electrical connector 204 illustrated in FIG. 2B, is a flexible circuit that carries electrical signal to and from the actuator of the hard disk drive 202. It is typically comprised of a plurality of electrical conductors encapsulated within an insulating material. The actuator flex cable provides electrical contact between electronics external to the housing and the actuator within the hard disk drive 202, which is supported on bearings allowing radial motion of the actuator about its pivot point. The radial motion of the actuator allows the read/write transducers supported on suspensions fixed to the actuator to access data tracks on the disk surfaces located at any radial position from the inside diameter of the disk to the outside diameter of the disk. Although a flexible circuit is illustrated as the electrical connector 204 in FIG. 2B, recognize that a rigid pin connector, for example, may constitute the electrical connector in other embodiments. Nevertheless, use of a flexible circuit provides more flexibility in design and assembly of components as it has built-in tolerance when used for connecting adjacent components and is generally not subject to precise alignment requirements associated with rigid electrical connectors. Further, when the flexible circuit is embedded within the base 208 to form a tortuous path as illustrated in, for example, FIG. 2B, further advantages are obtained as compared to use of rigid pin connectors as described further below. In a preferred embodiment, once the hard disk drive housing comprising the base 208 and cover 210 is sealed, at least that portion of the electrical connector 204 proximate its exit from the hard disk drive 202 at exiting region 212 is coated with metal 200.

In one embodiment, an electrical connector 204 comprising a flexible circuit extends through an opening in the base 208 and provides electrical contact between electronics external to the housing and the actuator within the hard disk drive 202, which electrical contact facilitates reading and recording of the data at any desired location on the at least one disk. According to one aspect of this embodiment, exiting region 212 proximate the electrical connector 204 comprises a recessed portion within the base 208. According to a further embodiment, the exiting region 212 provides an enlarged opening within the base 208 through which the electrical connector 204 may exit the hard disk drive 202 without direct constraint by the base 208. Advantageously, by eliminating direct constraint of the electrical connector 204 by the base 208, potential problems arising from expansion and contraction of the often dissimilar materials forming the electrical connector 204 and the base 208 during use of the hard disk drive 202 are minimized. For example, paths for leakage of a contained gaseous medium and/or entry of problematic electromagnetic waves are readily introduced by dissimilar rates of expansion and contraction between mating components.

According to one embodiment of the invention, a compliant constraint surrounds the electrical connector 204 in the exiting region 212. The compliant constraint accommodates differences in amounts of expansion and contraction arising between the electrical connector 204 and the base 208 during use of the hard disk drive 202 and seals the opening in the base 208 around the electrical connector 204. Preferably, the compliant constraint provides a smooth transition between the base 208 and the electrical connector 204, which makes for more controlled metal coating thereof. Any suitable material may be used for the compliant constraint. In an exemplary embodiment, prior to metal coating, the exiting region 212 of the electrical connector 204 is first filled with a potting compound (e.g., an epoxy potting compound such as entrochem 318, available from entrochem, inc. of Columbus, Ohio).

As illustrated in FIGS. 2B and 2C, an exemplary electrical connector 204 comprises an embedded flexible circuit. According to this embodiment, the electrical connector 204 is embedded within the base 208 of the hard disk drive 202 (e.g., by overmolding a plastic base 208 around the flexible circuit). Preferably, when embedded as such, the electrical connector 204 is positioned therein in a tortuous path to maximize changes of direction (e.g., direction of curvature) within the embedded section of the base 208. In one embodiment, the electrical connector 204 changes direction at least about three times. In a further embodiment, the electrical connector 204 changes direction at least about five times. In yet a further embodiment, the electrical connector 204 changes direction at least about seven times. As such, the embedded electrical connector 204 comprises a serpentine or labyrinth path through the base 208 according to an exemplary embodiment. By embedding the electrical connector 204 within a plastic base 208 as such, the likelihood that the path of such an electrical connector 204 as it exits the hard disk drive 202 will serve as an effective path for leakage of a contained gaseous medium and/or entry of problematic electromagnetic waves are further minimized.

According to another embodiment, at least one metal coating 200 is formed over a fill port 214 exiting a hard disk drive 202 (e.g., a port used to fill the hard disk drive 202 with helium), such as that fill port 214 illustrated in FIG. 2D. As further illustrated in FIG. 2E, a valve flap 216 operates within the fill port 214 during evacuation and/or filling of the hard disk drive 202. Prior to coating the hard disk drive 202 with the at least one metal coating 200, the fill port 214 is sealed via insertion of plug 218, which is illustrated in FIG. 2F, into plug cavity 220 of FIG. 2E. For ease of assembly, as illustrated in FIG. 2F, the plug 218 is secured to the hard disk drive 202 via a band 222 or other similar tethering mechanism according to an exemplary embodiment.

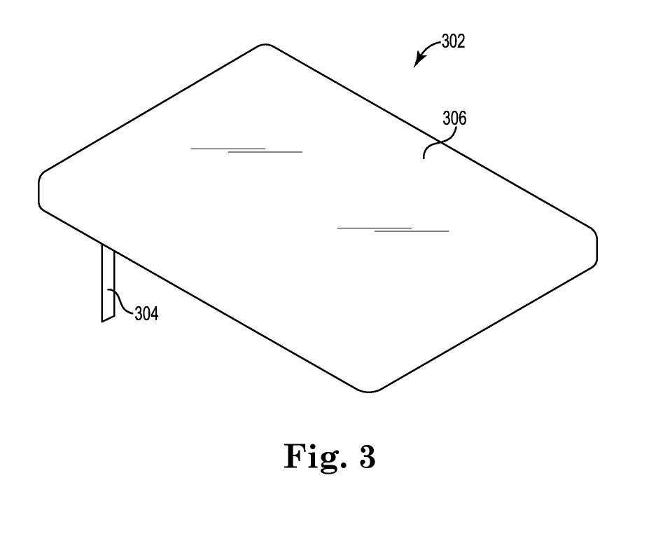

After sealing of the housing and coating of the hard disk drive 302 with the at least one metal coating (not shown), the hard disk drive 302 may, optionally, be encapsulated in a polymeric material 306 as illustrated in FIG. 3. According to one aspect of this further embodiment, the polymeric material 306 encapsulates all but the electrical connector 304. Any suitable polymeric material 306 may be used for the encapsulation, e.g., those materials used as coverings on the outermost surface of common household batteries. An exemplary polymeric material 306 comprises polyurethane. Further, any suitable methodology may be used to encapsulate the hard disk drive 302 with the polymeric material 306. For example, the polymeric material 306 may be applied using dip coating, spray coating (e.g., plasma coating), or label coating methodologies as known to those of ordinary skill in the art. The polymeric material 306 may provide protective and/or decorative properties to the hard disk drive 302 (e.g., functioning as a decorative label that also protects the underlying metal coating). In an exemplary embodiment, the polymeric material 306 comprises at least one graphic.

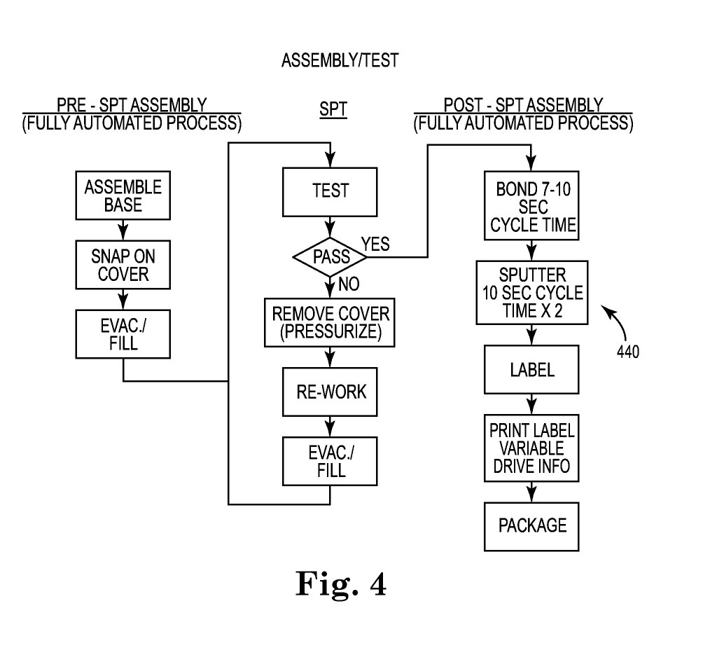

An exemplary method 440 of assembling and testing a hard disk drive according to the invention is illustrated in FIG. 4. During exemplary manufacture and assembly of a hard disk drive according to the invention, a cover and base are provided and enclosed around components internal to the hard disk drive within a clean room environment. When an electrical connector is also to be assembled such that it protrudes external to the housing, it is likewise assembled within the clean room environment. The enclosed housing can then be suspended by the electrical connector (e.g., flexible circuit) during the metal coating process, if desired, for processing efficiency.

Generally, a hard disk drive housing comprises at least two components. Any suitable mechanism can be used to mechanically couple components (e.g., a base and cover) of the hard disk drive housing. According to an exemplary embodiment, a top component and a bottom component snap-fit together to enclose a disk drive within the hard disk drive housing. The snap-fit design further facilitates improved sealing of the hard disk drive within the housing according to exemplary aspects of the invention.

According to one embodiment, as illustrated in FIG. 2G, the base 208 and the cover 210 are mechanically coupled via integrally formed male- and female-type connectors. In one variation of this embodiment, the base 208 comprises a male-type connector mechanically coupled to a female-type connector of the cover 210. In an alternate variation, the cover 210 comprises a male-type connector 224 mechanically coupled to a female-type connector 226 of the base 208. For example, the male-type connector 224 comprises a ridge and the female-type connector 226 comprises a groove according to a preferred embodiment. As such, the base 208 and the cover 210 are snap-fit (also referred to herein as snap-coupled) together.

In an exemplary embodiment, at least one of the two components of the hard disk drive housing consists essentially of a non-metallic material (e.g., a plastic). In a further embodiment, each of the two components of the hard disk drive housing consists essentially of a non-metallic material (e.g., a plastic). Use of non-metallic materials, such as plastic, affords many advantages. For example, use of such materials facilitates lighter weight hard disk drives and associated cost savings.

As a further example, use of moldable materials, facilitates design flexibility in that many performance-enhancing features (e.g., flow diverters and other features, some of which are described elsewhere herein) can be directly molded within components of the housing. One such feature relates to connectors for attachment of the hard disk drive within a computing framework. Conventionally, hard disk drives are connected within a computing framework for operation with other electrical components to perform data functions. Often, hard disk drives are attached via screws to rails supporting one or more hard disk drives. In order to decrease propagation of vibrations through such connections, integral attachment receivers (e.g., bores) can be molded into the housing when the housing component is formed of, for example, plastic. For example, one or more threaded bores for receipt of screws can be molded within one or more components of the housing during injection molding of the housing component. Advantageously, when screws or similar mechanical fasteners are threaded therein for attachment of hard disk drives within computing frameworks, propagation of vibrations through the attachment are minimized as compared to increased propagation of vibrations through metal-to-metal attachment mechanisms.

When snap-fit together according to exemplary embodiments of the invention, components of the housing are placed under tension, which advantageously increases stiffness of the material (e.g., plastic) comprising the same. When stiffness of the material increases, so does its strength. Thus, such a snap-fit design facilitates use of materials (e.g., plastic) otherwise not able to be effectively used for the bulk of, for example, a cover for a hard disk drive housing due to their degree of flexure. It is well understood that flexure of a hard disk drive cover must not be so great as to interrupt rotation of disks enclosure therein. Pressure testing and other methodologies known to those skilled in the art assist in determining flexure of such a cover. Further, thickness of the component under tension need not be as great as a similar component that would otherwise be secured to other components forming the housing due to the increased strength of the material forming the component, which translates into reduced flexure thereof. Further yet, additional flexibility is afforded in design of other components of the housing (e.g., non-horizontal portions) because of the improvements in component strength afforded by snap-fitting components of the housing according to the invention. Still further, tension introduced within the housing components snap-coupled together as such obviates the need for clamping of the components when bonding them together according to exemplary methods of sealing hard disk drives according to the invention.

In an exemplary embodiment, a hard disk drive of the invention comprises a composite housing. The composite housing comprises a base and a cover. The housing is understood to be a composite housing in that at least a portion of the housing comprises a laminate of at least one non-elastic plastic layer and at least one metal coating. According to one aspect of this embodiment, the plastic layer does not function as a viscoelastic material. Rather, in contrast to constrained layer dampers containing an internal viscoelastic material, the plastic layer of composite housings of the invention contributes a majority of the structural strength and rigidity existing in the composite housing. As such, in a preferred embodiment, thickness of the plastic layer is greater than thickness of the metal coating laminated thereto.

The metal coating may be formed over at least a portion of at least one exterior surface of the housing, at least a portion of at least one interior surface of the housing, or a combination thereof. In an exemplary embodiment, the metal coating is at least formed over essentially the entire exterior surface of the housing. In a further exemplary embodiment, the composite housing consists essentially of an interior plastic surface and an exterior metal surface. For example, a major portion of the composite housing may comprise plastic—e.g., a molded plastic component.

In a preferred embodiment, the hard disk drive is sealed essentially without using any discrete mechanical fasteners, whether those mechanical fasteners are positioned inside or outside the perimeter of any conventional seal (e.g., a rubber gasket seal). In contrast, mechanical fasteners, such as screws, are conventionally used to secure hard disk drive housings. However, openings in the housing around such fasteners have proven to be a conduit for not only leakage of a gaseous medium from within a hard disk drive, but also a conduit for electromagnetic waves entering the hard disk drive, where they can cause undesirable EMI. Even when such mechanical fasteners are positioned outside the perimeter of a conventional seal, improvements are still needed due to the tendency for such conventional seals to permit leakage between the hard disk drive and its external environment over an extended period of time. Thus, further advantages are obtained when employing this embodiment of the invention, where discrete mechanical fasteners are essentially eliminated from portions of the hard disk drive where housing components (e.g., the base and cover of the housing) are sealed together.

During the process of enclosing the cover 210 and base 208 around the internal components, any suitable sealing material 221 may be positioned between the cover and base, such as shown in FIG. 2C, for sealing engagement of the hard disk drive housing in an exemplary embodiment. For example, conventional rubber gasket seals or other sealing materials such as irradiation-crosslinked, closed-cell foam (e.g., that commercially available under the VOLARA trade designation—Sekisui Voltek of Lawrence, Mass.) can be used for such a seal. Such a sealing engagement facilitates short-term hermetic sealing of the hard disk drive housing, but enhanced sealing using at one metal coating according to the present invention is desirable for long term performance.

As an alternative to use of conventional sealing materials positioned between the cover and the base, which conventional sealing materials typically decrease processing efficiency and increase manufacturing costs, a temporary sealing tape is used to seal the interface between the cover and the base according to one aspect of the invention. Any suitable adhesive tape can be used for this purpose. Unlike conventional temporary sealing tapes used in the disk drive industry, however, exemplary temporary sealing tapes according to preferred embodiments of the invention do not include metallic or other components that block transmission of infrared radiation. That is, preferably the temporary sealing tape is infrared-transparent so that the housing can be permanently sealed efficiently after application of the temporary sealing tape and testing of the hard disk drive. For example, the housing can be permanently sealed using through transmission infrared bonding without removal of the temporary sealing tape when the tape is infrared-transparent. An exemplary temporary sealing tape is entrofilm 575, available from entrotech, inc. of Columbus, Ohio, which was found to provide adequate sealing of the hard disk drive on a temporary basis during testing thereof. Further, potential for contamination of the hard disk drive from adhesive residue is minimized due to balance of adhesion properties in such a tape. For example, the adhesive layer in such a tape is anchored to its backing at a greater strength than its anchorage to the hard disk drive surface on which it is used. Thus, if the temporary sealing tape must be removed from the hard disk drive during testing and re-working of the drive, risk of adhesive contamination is minimized as the tape can be easily peeled cleanly away from the hard disk drive instead of necessitating cutting therethrough to separate the housing components when re-working the drive.

In one embodiment, the base and cover are assembled around components internal to the hard disk drive in not only a clean room environment, but also an environment filled with the desired gaseous medium (when the desired medium is other than atmospheric air). In another embodiment, after enclosing the base and the cover around internal components to the disk drive and temporarily sealing the disk drive housing any suitable methodology as known to those skilled in the art, the disk drive is evacuated and filled with the desired gaseous medium (when the desired medium is other than atmospheric air). A fill port or other conventional methodology can be used for filling the disk drive with the desired gaseous medium using any suitable methodology as known to those skilled in the art according to this embodiment. The disk drive then preferably undergoes routine testing and re-working, if necessary. Once the disk drive passes such testing, each of the one or more metal coatings is then applied to the desired surface of the hard disk drive housing any suitable method.

As discussed above, while the material underlying the one or more metal coatings may be metal itself, further advantages are obtained by fabricating the underlying hard disk drive housing or components thereof (e.g., a base or cover) from a lighter weight material (i.e., a material that is lighter than metal). Lighter weight materials include, for example, ceramics, plastics, and many composites (e.g., metal matrix composites and glass-filled particulate plastics). The lighter weight provided by these materials translates into lighter weight assemblies including the hard disk drive, which makes for not only often more desirable features for the user of such assemblies but also beneficially reduces manufacturing and shipping costs associated with such assemblies. Suitable plastic materials include, for example, polycarbonate and polybutylterepthalate. An exemplary hard disk drive according to the invention comprises polycarbonate housing components, with the uncoated polycarbonate cover weighing about 0.031 pounds (about 14 grams) and the uncoated polycarbonate base weighing about 0.026 pounds (about 12 grams).

To further enhance disk drive performance, an insert 230 is molded (e.g., insert-molded) into the base 208 of the hard disk drive housing as illustrated in FIGS. 2H-2I. The insert 230 is positioned between the actuator and housing and provides, for example, positional stability between the actuator assembly and spindle motor of the hard disk drive 202, which translates into damping of vibrations that can be introduced through rotation of disks within the hard disk drive 202. Problematic harmonics from such vibrations become more evident upon operation of multiple hard disk drives connected within a rack.

The insert 230 comprises any suitable shape to provide desired positional stability between the actuator assembly and spindle motor of the hard disk drive 202. Positional stability is imparted due, in part, to relative stiffness of the insert 230 as compared to stiffness of the material (e.g., plastic) forming the base 208. Generally, the insert 230 comprises any suitable material. In an exemplary embodiment, the insert 230 comprises a ceramic or stainless steel.

In a further embodiment, the insert 230 is coated with a damping elastomer prior to being insert-molded within the base 208. Advantageously, such an insert 230 can function as a damped metal laminate, being selectively and precisely positioned within the hard disk drive 202, obviating the need for an entire hard disk drive cover or housing to be formed of a damped metal laminate and providing an associated weight savings.

According to a further variation of this embodiment, the insert 230 comprises a heat sink 232, such as that illustrated in FIG. 2I. According to this embodiment, one or more fins 234 on the insert 230 protrudes from the base 208 to function as the heat sink 232 to dissipate excess heat from within the hard disk drive 202. In an exemplary embodiment, where the hard disk drive 202 comprises a metal coating (not shown on the base 208 of the hard disk drive 202 illustrated in FIG. 2I), incorporation of an insert 230 with fins 234 in this manner facilitates thermal conductivity and enhances performance of the modified insert 230 as a heat sink.

Advantages associated with hard disk drives and related methods comprising metal coatings of the present invention include, for example, one or more of improved shielding from EMI or ESD as well as improved containment of a gaseous medium within an enclosed hard disk drive. Within the sealed environment of hard disk drives of the invention, a gas having a density less than that of atmospheric air can be effectively employed. For example, a gaseous medium comprising at least one of nitrogen, helium, or other noble gases can be employed therein, alone or in combination with one or more of each other and/or air.

In an exemplary embodiment, an improved hard disk drive of the invention is capable of providing and maintaining an adequate sealed environment for at least five years. An adequate sealed environment is one in which hard disk drive performance is not significantly affected due to leakage. According to one embodiment, at least about 90% by volume, preferably at least about 95% by volume, of a gaseous medium originally contained within a hard disk drive remains after five years. Any suitable methodology can be used to detect leakage of a gaseous medium from a hard disk drive and amounts thereof. In order to adequately seal the gaseous medium within the hard disk drive, use of expensive gasket seals is not necessary according to preferred embodiments of the invention. However, such gasket seals may be used, if desired.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. Further, while the present invention has been described with respect to a hard disk drive, it should be understood that the present invention also finds utility in other data storage devices—e.g., optical and magneto-optical storage devices.

1. A hard disk drive comprising at least one metal coating formed over at least one exterior surface of a hard disk drive housing, wherein the hard disk drive is hermetically sealed.

2. The hard disk drive of claim 1, wherein the at least one metal coating is formed over essentially the entire exterior surface of the hard disk drive housing.

3. The hard disk drive of claim 2, wherein the at least one metal coating comprises a uniformly thick coating of the same metal or combinations thereof on the entire exterior surface of the hard disk drive housing.

4. The hard disk drive of claim 1, wherein the at least one metal coating is formed over a portion of an electrical connector proximate exit of the electrical connector from the hard disk drive housing.

5. The hard disk drive of claim 1, wherein the at least one metal coating is formed over a fill port used to fill the hard disk drive with a gaseous medium.

6. The hard disk drive of claim 1, wherein the at least one metal coating comprises aluminum, chrome, copper, stainless steel, or a combination thereof.

7. The hard disk drive of claim 1, comprising at least two metal coatings.

8. The hard disk drive of claim 1, wherein more than one metal coating is formed over the exterior surface of the hard disk drive housing and wherein a most exterior metal coating comprises chrome or stainless steel.

9. The hard disk drive of claim 1, wherein the at least one metal coating comprises a stainless steel coating having a thickness of about one micron formed over a copper coating having a thickness of at least about two microns.

10. The hard disk drive of claim 1, wherein the at least one metal coating comprises multiple contiguous layers.

11. The hard disk drive of claim 1, wherein the at least one metal coating comprises at least about four individual layers.

12. The hard disk drive of claim 1, wherein combined thickness of the one or more metal coatings is about one micron thick.

13. The hard disk drive of claim 1, wherein combined thickness of the at least one metal coating is at least about fifty microns thick.

14. The hard disk drive of claim 1, wherein combined thickness of the at least one metal coating is less than about two-hundred microns thick.

15. The hard disk drive of claim 1, wherein the hard disk drive is capable of providing and maintaining an adequate sealed environment for a gaseous medium other than atmospheric air for at least five years.

16. The hard disk drive of claim 1, wherein at least a major portion of the hard disk drive housing comprises a material that is lighter in weight than metal.

17. A method of forming the hard disk drive of claim 1, comprising steps of:
providing a cover and a base for the hard disk drive housing;
optionally, positioning a sealing material between the cover and the base for sealing engagement of the hard disk drive housing;
enclosing the cover and the base around components internal to the hard disk drive;
optionally, evacuating and filling the hard disk drive with a desired gaseous medium when the desired gaseous medium is other than atmospheric air; and
forming the at least one metal coating on the at least one exterior surface of the hard disk drive housing.

18. The method of claim 17, wherein the step of forming the at least one metal coating on the at least one exterior surface of the hard disk drive housing comprises using plating techniques.

19. The method of claim 17, wherein the step of forming the at least one metal coating on the at least one exterior surface of the hard disk drive housing comprises using sputter coating.

20. The method of claim 17, wherein the step of forming the at least one metal coating on the at least one exterior surface of the hard disk drive housing comprises using spray coating.
